(19) United States
(12) Patent Application Publication
(10) Pub. No.: US 2007/0170474 A1
(43) Pub. Date: Jul. 26, 2007

(54) SEMICONDUCTOR DEVICE AND METHOD OF FABRICATING THE SAME

(75) Inventor: Hirohisa KAWASAKI, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/625,985

(22) Filed: Jan. 23, 2007

(30) Foreign Application Priority Data
Jan. 24, 2006 (JP) 2006-015602

(51) Int. Cl. H01L 29/76

(52) U.S. Cl. 257/288

(57) ABSTRACT

A semiconductor device according to one embodiment of the present invention includes: a semiconductor substrate; a non-planar type transistor region having at least one of a fin type transistor region including a fin type transistor in which a current is induced to flow through side faces of a fin formed approximately vertically to a surface of the semiconductor substrate in a direction approximately parallel to the surface of the semiconductor substrate, and a tri-gate type transistor region including a tri-gate type transistor in which a channel is formed in three surfaces having side faces and an upper surface of a fin formed approximately vertically to the surface of the semiconductor substrate, and thus a current is induced to flow through the three surfaces in a direction approximately parallel to the surface of the semiconductor substrate; and a filling material for isolation in the non-planar type transistor region within the semiconductor substrate and which has a plurality of regions having different heights.

### CROSS-REFERENCE TO RELATED APPLICATIONS

This application is based upon and claims the benefit of priority from prior Japanese Patent Application No. 2006-015602, filed Jan. 24, 2006, the entire contents of which are incorporated herein by reference.

### BACKGROUND OF THE INVENTION

The present invention relates to a semiconductor device, and more particularly to a semiconductor device including a fin type transistor in which a current is induced to flow through side faces of a fin formed nearly vertically to a surface of a substrate in a direction nearly parallel to the surface of the substrate.

In order to improve problems involved in a planar type transistor which has a two-dimensional structure and which is the mainstream of the current semiconductor technology, that is to say, in order to realize an improvement in a short channel effect, an increase in current driving capability, and higher integration, semiconductor devices each having a three-dimensional structure are examined. Of them, in a fin type transistor in which a channel is formed on two side faces of a fin formed nearly vertically to a surface of a substrate, and thus a current is induced to flow in a direction nearly parallel to the surface of the substrate, a gate electrode is formed so as to hold the fin between both sides of the gate electrode, which makes it possible to suppress the short channel effect. In addition, since the effective channel width can be increased by increasing a height of the fin, the current driving capability is also improved without increasing an occupation area. Moreover, since the reducing of a thickness of the fin allows an impurity concentration of the substrate to be reduced, not only the current driving capability is improved, but also the dispersion of the threshold voltages decreases.

With regard to this technique, there is given a method of fabricating a device to be formed with which a thickness of an SOI layer is controlled by using an SOI substrate to change structures of a fin type transistor, a planar type transistor and the like, thereby giving these transistors desired characteristics. This method, for example, is disclosed in US-B-6911383. In addition, there is given a formed device in which widths of a fin type transistor and a planar type transistor which are formed by trimming an SOI film deposited on a substrate are changed, thereby giving these transistors desired characteristics. This formed device, for example, is disclosed in a literary document of Fu-Liang Yang, et al.: “Strained FIP-SOI (FinFET/FD/PD-SOI) for Sub-65 nm CMOS Scaling”, 2003 Symposium on VLSI Technology Digest of Technical Papers.

However, with the above-mentioned prior art, for example, a height of the fin of the fin type transistor formed in a semiconductor device depends on a thickness of an SOI layer, and thus the height of the fin cannot be made not smaller than a thickness of the SOI layer. As a result, when the height of the fin is intended to be changed, there is a limit in a range of the height of the fin. For example, it is essential to an improvement in a static noise margin (SNM) in an SRAM cell that the performance of a driver transistor becomes superior to that of a transfer transistor. In addition, in the SRAM cell using the fin type transistor, making the fin height of the driver transistor higher than that of the transfer transistor allows the improvement in the SNM to be realized without increasing a cell area. However, with the above-mentioned technique using the SOI substrate, it is difficult to make the improvement in the SNM by changing the fin height because of a small variable rate on a height.

### BRIEF SUMMARY OF THE INVENTION

A semiconductor device according to one embodiment of the present invention includes:

a semiconductor substrate;

a non-planar type transistor region having at least one of a fin type transistor region including a fin type transistor in which a current is induced to flow through side faces of a fin formed approximately vertically to a surface of the semiconductor substrate in a direction approximately parallel to the surface of the semiconductor substrate, and a tri-gate type transistor region including a tri-gate type transistor in which a channel is formed in three surfaces having side faces and an upper surface of a fin formed approximately vertically to the surface of the semiconductor substrate, and thus a current is induced to flow through the three surfaces in a direction approximately parallel to the surface of the semiconductor substrate; and

a filling material for isolation in the non-planar type transistor region within the semiconductor substrate and which has a plurality of regions having different heights.

A semiconductor device according to another embodiment of the present invention includes:

a semiconductor substrate;

a planar type transistor region including a planar type transistor in which a current is induced to flow in a direction approximately parallel to a surface of the semiconductor substrate;

a fin type transistor region including a plurality of fin type transistors in which a current is induced to flow through side faces of a fin formed approximately vertically to the surface of the semiconductor substrate in a direction approximately parallel to the surface of the semiconductor substrate;

a filling material for isolation in the fin type transistor region within the semiconductor substrate and which has a plurality of regions having different heights; and

a filling material for isolation in the planar type transistor region within the semiconductor substrate and which has a height higher than that of the filling material for isolation in the fin type transistor region.

A method of fabricating a semiconductor device according to still another embodiment of the present invention includes:

forming a trench on a semiconductor substrate;

filling a dielectric material in the trench;

etching back the dielectric material film in a fin type transistor region in which a plurality of fin type transistors are intended to be formed while an etching depth is changed every predetermined region, thereby forming a filling material for isolation in the fin type transistor region having a plurality of regions having different heights; and

forming the fin type transistors in the fin type transistor region.

### BRIEF DESCRIPTION OF THE DRAWINGS

FIGS. 1A to 1I are respectively cross sectional views showing processes for fabricating a semiconductor device according to a first embodiment of the present invention;

FIG. 2 is a perspective view of the semiconductor device according to the first embodiment of the present invention;

FIGS. 3A to 3I are respectively cross sectional views showing processes for fabricating a semiconductor device according to a second embodiment of the present invention;

FIG. 4 is a cross sectional view of a semiconductor device according to a third embodiment of the present invention;

FIG. 5 is a layout view of an SRAM cell according to a fourth embodiment of the present invention;

FIG. 6 is a circuit diagram of the SRAM cell according to the fourth embodiment of the present invention; and

FIG. 7 is a cross sectional view of a semiconductor device according to the fourth embodiment of the present invention.

### DETAILED DESCRIPTION OF THE INVENTION

A semiconductor device according to a first embodiment of the present invention includes a planar type transistor and a fin type transistor.

The planar type transistor is formed through isolation using a buried insulating film buried in a trench formed on an Si substrate, and includes a gate electrode formed on the Si substrate through a gate insulating film, a channel region formed in a region below the gate electrode in the Si substrate, and a source region and a drain region which are formed in the Si substrate and between which the channel region is formed.

The fin type transistor is formed through the isolation using the buried insulating film buried in the trench formed on the Si substrate, and includes a fin formed nearly vertically to a surface of the Si substrate, a gate electrode formed on both side faces of the fin through a gate insulating film, a channel region which is formed in a region, which is held between two portions of the gate electrode, of the fin, and a source region and a drain region which are formed in the fin and between which the channel region is formed. A concrete structure of the semiconductor device according to the first embodiment of the present invention will be described in detail hereinafter while a method of fabricating the semiconductor device of the first embodiment will be described in detail.

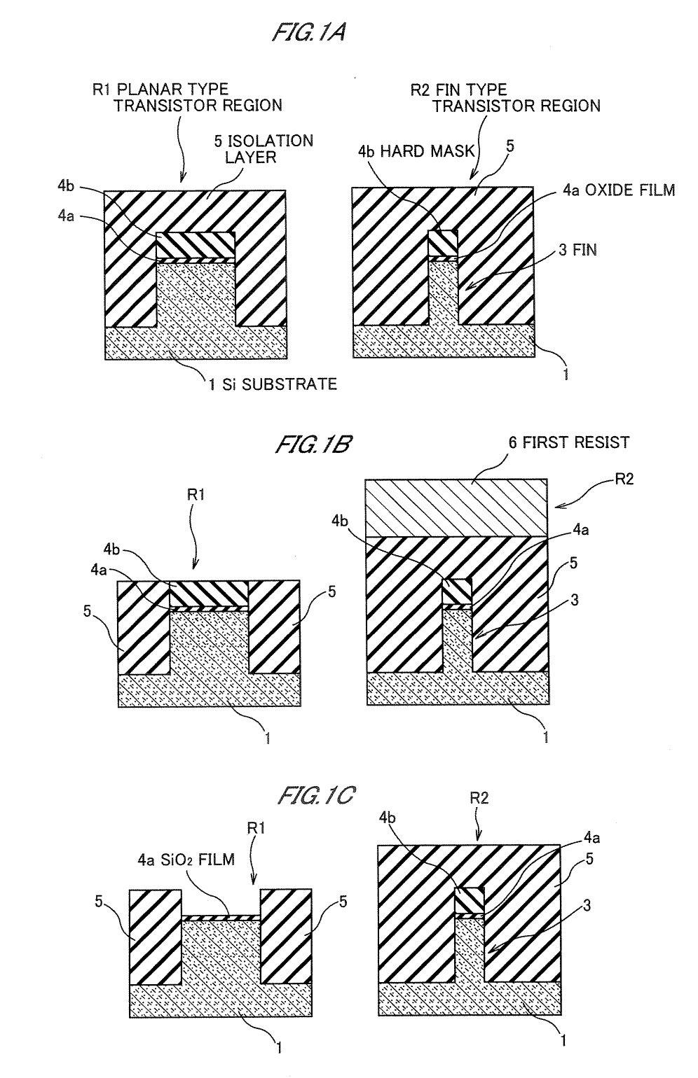

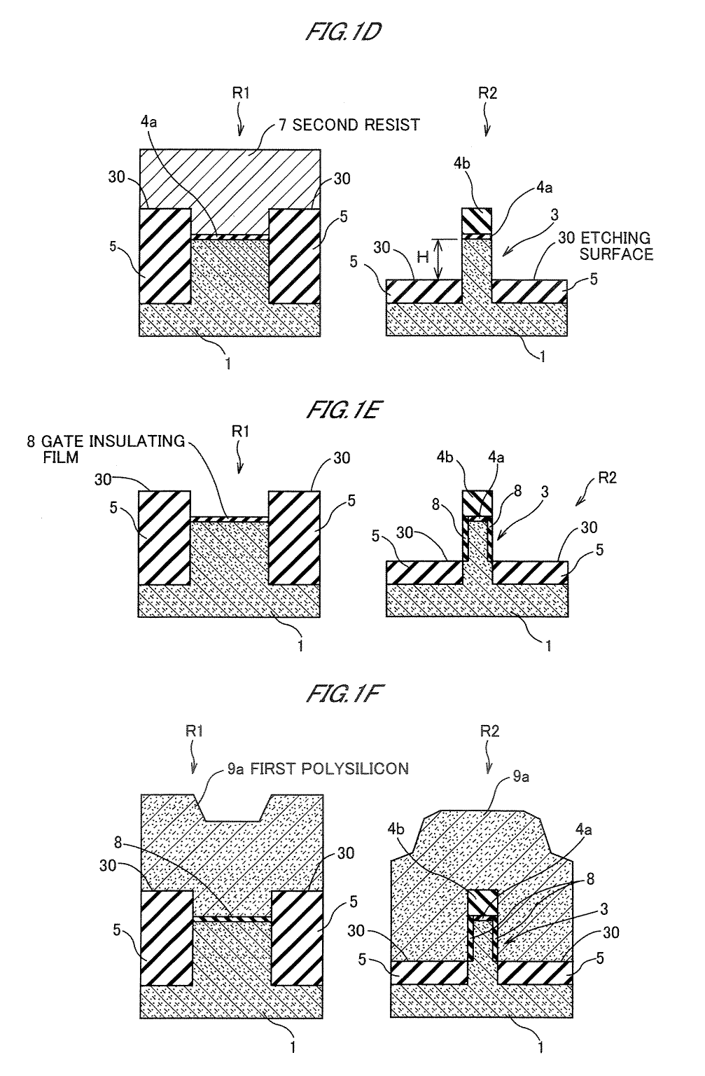

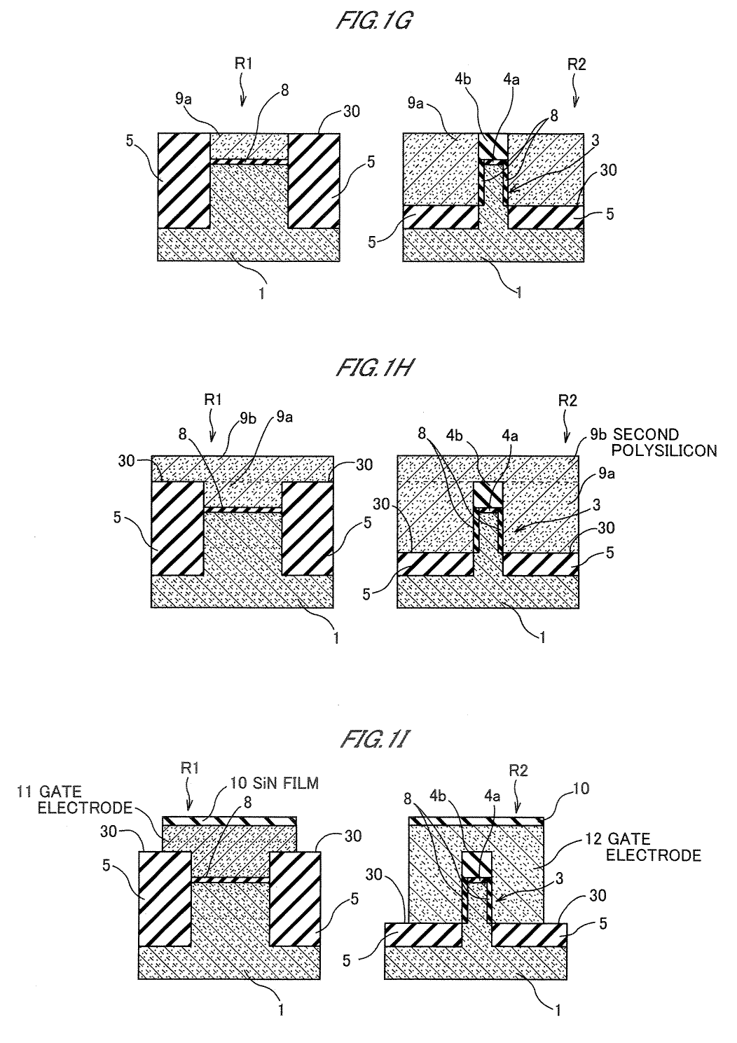

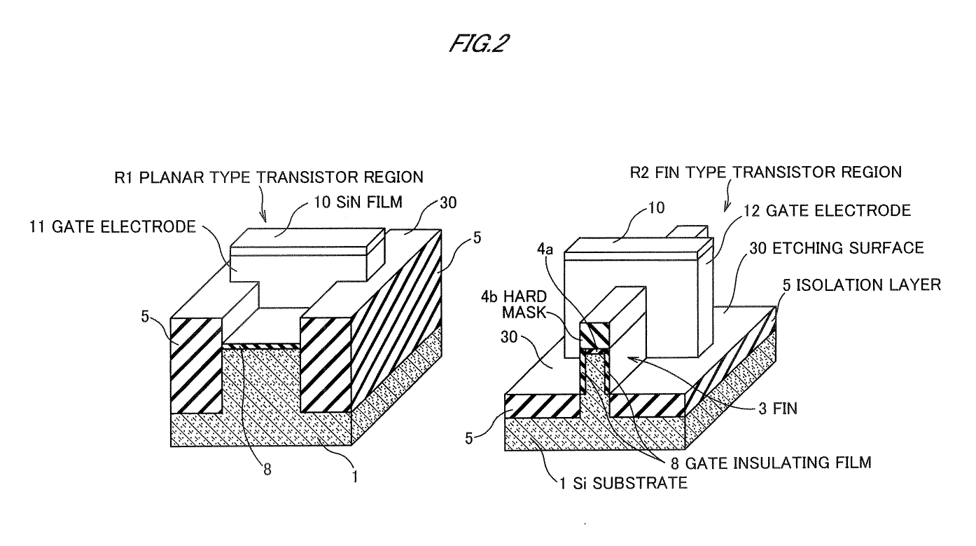

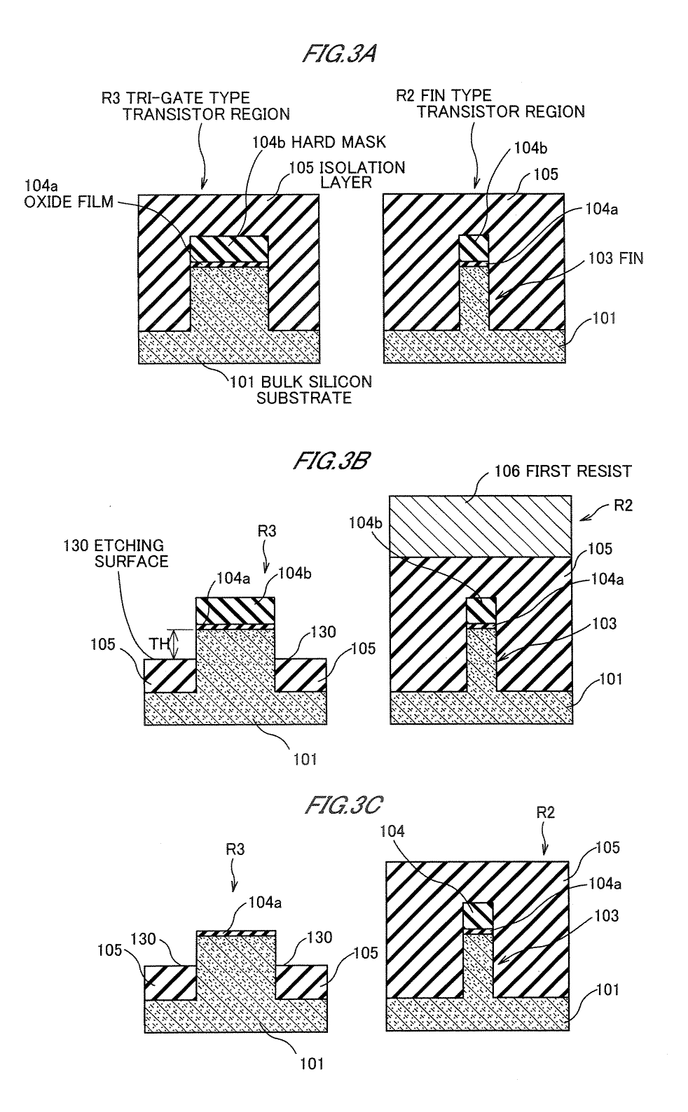

FIGS. 1A to 1I are respectively cross sectional views showing processes for fabricating the semiconductor device , in which the planar type transistor and the fin type transistor formed, according to the first embodiment of the present invention. In these figures, cross sections of a planar type transistor region R1 in respective fabricating stages are shown in a left-hand side, and cross sections of a fin type transistor region R2 in respective fabricating stages are shown in a right-hand side.

FIG. 1A shows processes from trench etching made for isolation in an Si substrate 1 to deposition and flattening of an insulating film. Firstly, an oxide film 4a and a hard mask 4b made from an SiN film are formed in each of the planar type transistor region RI and the fin type transistor region R2 on the Si substrate 1 as a bulk silicon substrate in accordance with a shape of the planar type transistor and a shape of a fin 3 of the fin type transistor. A trench for isolation is formed in predetermined shape in a photolithography process using the hard mask 4b. A depth of the trench in this process determines a maximum height of the fin 3. As an example, a height of the fin 3 is set in the range of 50 to 100 nm, and a width thereof is set as being about 10 nm. Next, an isolation layer 5 made of dielectric material, such as SiO₂, is deposited in the trench portion so as to cover the hard mask 4b by utilizing a plasma activated chemical vapor deposition (PCVD) method or the like, and is then flattened by utilizing a chemical mechanical polishing (CMP) method.

FIG. 1B shows a process for forming the planar type transistor region R1. After a first photo resist 6 is formed on a region, including the fin type transistor region R2, other than the planar type transistor region R1 by utilizing a photolithography technique or the like, the isolation layer 5 (a filling material for isolation in the planar type transistor region R1) is selectively etched away by utilizing a reactive ion etching (RIE) method or the like. That is to say, the isolation layer 5 is selectively etched away until an upper end of the hard mask 4b is exposed. However, the isolation layer 5 may be etched back until an upper surface portion of the Si substrate 1 is exposed, that is, a height of a portion intended to become a channel is reached. On the other hand, no isolation layer 5 (a filling material for isolation in the fin type transistor region R2) is etched away in the fin type transistor region R2 because the first photo resist 6 is formed thereon.

FIG. 1C shows a process for removing the hard mask 4b in the planar type transistor region R1. After the first photo resist 6 is removed, the hard mask 4b is removed in wet etching processing using a phosphoric acid.

FIG. 1D shows an etching process for determining a height of the fin type transistor region R2. A second photo resist 7 is formed on a region, including the planar type transistor region R1, other than the fin type transistor region R2 by utilizing the photolithography technique or the like, and the isolation layer 5 in the fin type transistor region R2 is etched back by utilizing the RIE method or the like. Here, the etching processing is continuously performed until a height H of the fin 3 becomes a predetermined value. The height H of the fin 3 is set in accordance with a driving current of the fin type transistor.

In this process, the etching processing can be performed so that the heights H of a plurality of fins 3 of the fin type transistor region R2 are made different from one another. That is to say, addition of a photo resist-forming process using a photolithography technique and the like to the process for the etching processing results in that an amount of etched back isolation layer 5 allowing the height H of the fin 3 to be reduced is made selectively less. In the manner described above, the amount of etched back isolation layer 5 is adjusted when necessary, which makes it possible to form a plurality of fin type transistors having different fin height H.

On the other hand, no isolation layer 5 is etched away in the planar type transistor region R1 because the second photo resist 7 is formed thereon through the process for the etching processing in this stage. The isolation layer 5 as the buried insulating film in each of the planar type transistor region R1 and the fin type transistor region R2 has different etching surfaces 30 in such etching processing. As a result, each of the channel region, and the source region and the drain region which are formed in the fin 3 has a width corresponding to a film thickness of the buried insulating film which has been subjected to the etching processing.

FIG. 1E shows a process for forming a gate insulating film. After the second photo resist 7 and the oxide film 4a in the planar type transistor region R1 are removed, a gate insulating film 8 made of SiO₂ or the like is formed by performing thermal oxidation. This process for forming the gate insulating film 8 is performed for both the planar type transistor region R1 and the fin type transistor region R2. Thus, the gate insulating film 8 is formed on each of both side faces of the fin 3. Here, addition of a photolithography process and an oxidation process makes it possible to form two or more kinds of oxide films within the same substrate. Thus, for example, different oxide films can also be formed in the planar type transistor region R1 and the fin type transistor region R2, respectively.

FIG. 1F shows a process for depositing a polysilicon layer. A first polysilicon layer 9a is deposited on each of the planar type transistor region R1 and the fin type transistor region R2 by utilizing the PCVD method or the like.

FIG. 1G shows a process for flattening the first polysilicon layer 9a. The first polysilicon film 9a deposited on each of the planar type transistor region R1 and the fin type transistor region R2 is flattened by utilizing the CMP method using the hard mask 4b in the fin type transistor region R2 as a stopper.

FIG. 1H shows a process for depositing a polysilicon layer. A second polysilicon layer 9b is deposited on each of the planar type transistor region R1 and the fin type transistor region R2 by utilizing the PCVD method or the like.

Note that, after completion of the process for depositing the first polysilicon layer 9a shown in FIG. 1F, the first polysilicon layer 9a is flattened to such a position that no hard mask 4b is exposed, which makes it possible to form the same structure as that shown in FIG. 1H without depositing the second polysilicon film 9b. With this method, however, it is not easy to control the height of the polysilicon layer formed in each of the planar type transistor region R1 and the fin type transistor region R2. As a result, the process dispersion of the flattening processing becomes easy to necessarily exert the influence on this process.

As shown in FIG. 1I, an SiN film 10 is formed as a hard mask on the second polysilicon layer 9b in each of the planar type transistor region R1 and the fin type transistor region R2, and the first polysilicon layer 9a and the second polysilicon layer 9b are then selectively etched away using the SiN film 10 as the mask by utilizing the RIE method, thereby forming gate electrodes 11 and 12. Thus, the basic shapes of the planar type transistor and the fin type transistor shown in FIG. 2 are formed.

After that, after completion of processes for formation of a pn junction for formation of the source region and the drain region, formation of a pn junction for contact with a source electrode and a drain electrode, formation of a gate wiring, and a source wiring and a drain wiring, and the like, the semiconductor device in which the planar type transistor and the fin type transistor are formed is completed.

A semiconductor device according to a second embodiment of the present invention includes a tri-gate type transistor and a fin type transistor.

The tri-gate type transistor is formed through isolation using a buried insulating film buried in a trench formed on an Si substrate, and includes a tri-gate region (fin) which is formed nearly vertically to a surface of the Si substrate, a gate electrode which is formed on both side faces and an upper surface of the tri-gate region (fin) through a gate insulating film, a channel region which is formed in the vicinity of the gate electrode, and a source region and a drain region which are formed in both end portions of the channel region, respectively, that is, on both side faces and an upper surface of a silicon region. A concrete structure of the semiconductor device according to the second embodiment of the present invention will be described in detail hereinafter while a method of fabricating the semiconductor device of the second embodiment will be shown hereinafter.

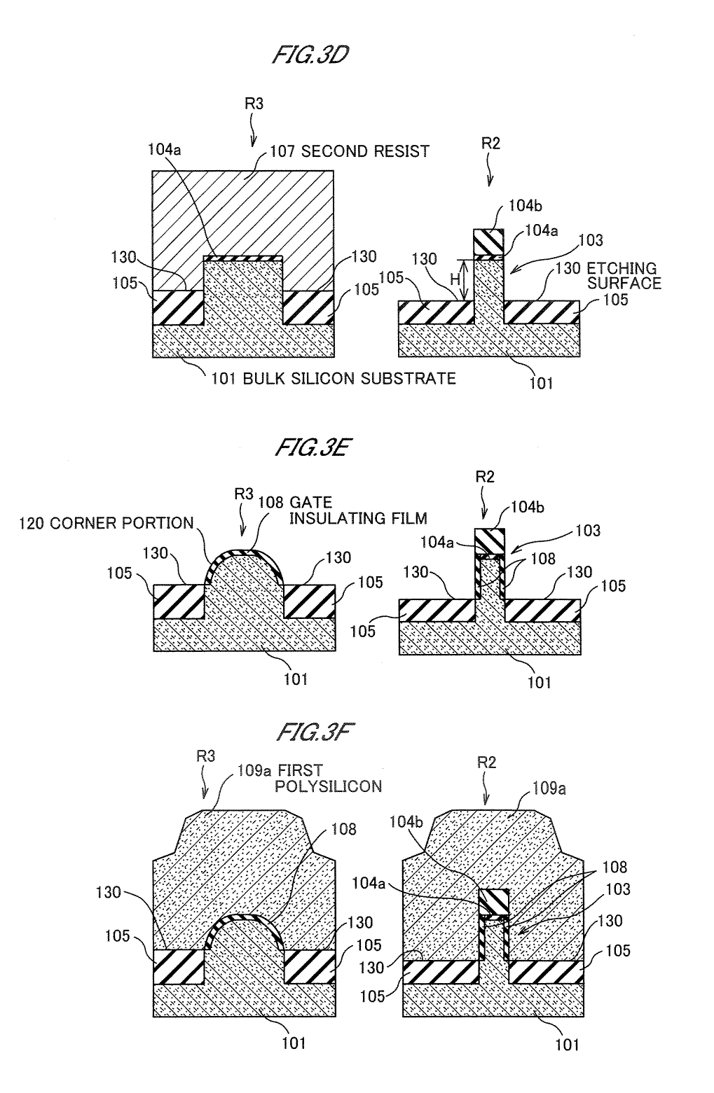

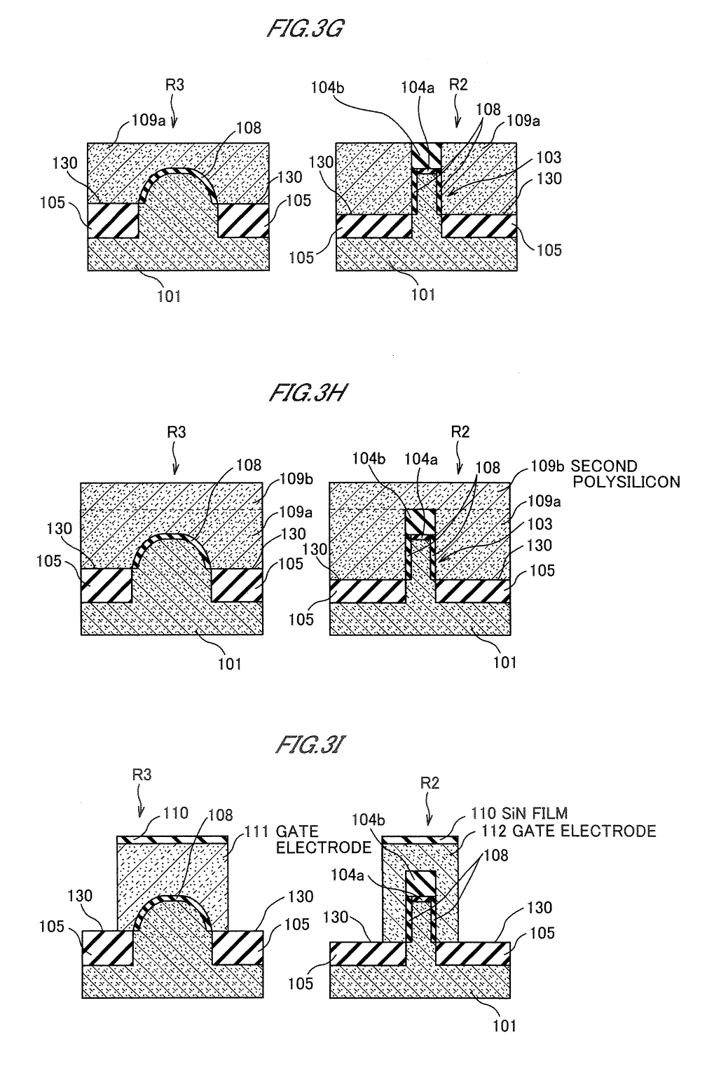

FIGS. 3A to 3I are respectively cross sectional views showing processes for fabricating the semiconductor device, in which the tri-gate type transistor and the fin type transistor are formed, according to the second embodiment of the present invention. In these figures, cross sections of a tri-gate type transistor region R3 in respective fabricating stages are shown in a left-hand side, and cross sections of a fin type transistor region R2 in respective fabricating stages are shown in a right-hand side.

FIG. 3A shows processes from trench etching made for isolation to an Si substrate 101 to deposition and flattening of an insulating film. Firstly, an oxide film 104a and a hard mask 104b made from an SiN film are formed in each of the tri-gate type transistor region R3 and the fin type transistor region R2 on the Si substrate 101 as a bulk silicon substrate in accordance with a shape of the tri-gate transistor and a shape of a fin 103 of the fin type transistor. A trench for isolation is formed in predetermined shape in a photolithography process using the hard mask 104b. A depth of the trench in this process determines a maximum height of the fin 103. Next, an isolation layer 105 is deposited as a buried insulating film in the trench portion so as to cover the hard mask 104b by utilizing the PCVD method or the like, and is then flattened by utilizing the CMP method.

FIG. 3B shows a process for forming the tri-gate type transistor region R3. After a first photo resist 106 is formed on a region, including the fin type transistor region R2, other than the tri-gate type transistor region R3 by utilizing the photolithography technique or the like, the isolation layer 105 (a filling material for isolation in the tri-gate type transistor region R3) is etched by utilizing the RIE method or the like. That is to say, the isolation layer 105 is etched back until a position of a set height TH of each side face gate of the tri-gate type transistor is reached. On the other hand, no isolation layer 105 is etched away in the fin type transistor region R2 because the first photo resist 106 is formed thereon.

FIG. 3C shows a process for removing the hard mask 104b in the tri-gate type transistor region R3. After the first photo resist 106 is removed, the hard mask 104b is removed in wet etching processing using a phosphoric acid.

FIG. 3D shows an etching process for determining a height of the fin 103 of the fin type transistor region R2. A second photo resist 107 is formed on a region, including the tri-gate type transistor region R3, other than the fin type transistor region R2 by utilizing the photolithography technique or the like, and the isolation layer 105 in the fin type transistor region R2 is etched back by utilizing the RIE method or the like. Here, the etching processing is continuously performed until a height H of the fin 103 becomes a predetermined value. The height H of the fin 103 is set in accordance with a driving current of the fin type transistor.

In this process, the etching processing can be performed so that the heights H of a plurality of fins 103 of the fin type transistor region R2 are made different from one another. That is to say, addition of a photo resist-forming process using the photolithography technique and the like to the process for the etching processing results in that an amount of etched back isolation layer 105 allowing the height H of the fin 103 to be reduced is made selectively less. In the manner described above, the amount of etched back isolation layer 105 is adjusted when necessary, which makes it possible to form a plurality of fin type transistors having different fin height H.

On the other hand, no isolation layer 105 is etched away in the tri-gate type transistor region R3 because the second photo resist 107 is formed thereon through the process for the etching processing in this stage. The isolation layer 105 as the buried insulating film in each of the tri-gate type transistor region R3 and the fin type transistor region R2 has different etching surfaces 130 in such etching processing. As a result, each of the channel region, and the source region and the drain region which are formed in the fin 103 has a width corresponding to a film thickness of the buried insulating film which has been subjected to the etching processing.

Note that, the etching processing can be performed for the tri-gate type transistor region R3 as well so that the fin heights of a plurality of tri-gate type transistors are made different from one another through the same process as that for the fin type transistor region R2 described above. That is to say, a photo resist is formed on the fin having the height which is intended to be made small and its vicinity, and an amount of etched back isolation layer 105 is made selectively less. In the manner described above, the amount of etched back isolation layer 105 is adjusted when necessary, which makes it possible to form a plurality of tri-gate type transistors having different heights TH.

FIG. 3E shows a process for forming a gate insulating film. After the second photo resist 107 and the oxide film 104a in the tri-gate type transistor region R3 are removed, a portion constituting the fin of the tri-gate type transistor is subjected to rounding processing for rounding off corner portions 120 by performing plasma-assisted oxidation or an H₂ anneal. On the other hand, no rounding processing is performed for the fin type transistor region R2 because the hard mask 104b is formed on the fin type transistor region R2. After that, a gate insulating film 108 made of SiO₂ or the like is formed by performing the thermal oxidation. This process for forming the gate insulating film 108 is performed for both the tri-gate type transistor region R3 and the fin type transistor region R2. Thus, the gate insulating film 108 is formed on each of both side faces of the fin 103 in the fin type transistor region R2. Also, the gate insulating film 108 is formed on each of three surfaces having both side faces and an upper surface of the fin in the tri-gate type transistor region R3.

FIG. 3F shows a process for depositing a polysilicon layer. A first polysilicon layer 109a is deposited on each of the tri-gate type transistor region R3 and the fin type transistor region R2 by utilizing the PCVD method or the like.

FIG. 3G shows a process for flattening the first polysilicon layer 109a. The first polysilicon layer 109a deposited on each of the tri-gate type transistor region R3 and the fin type transistor region R2 is flattened by utilizing the CMP method using the hard mask 104b in the fin type transistor region R2 as a stopper.

FIG. 3H shows a process for depositing a polysilicon layer. A second polysilicon layer 109b is deposited on each of the tri-gate type transistor region R3 and the fin type transistor region R2 by utilizing the PCVD method or the like.

Note that, after completion of the process for depositing the first polysilicon layer 109a shown in FIG. 3F, the first polysilicon layer 109a is flattened to such a position that no hard mask 104b is exposed, which makes it possible to form the same structure as that shown in FIG. 3H without depositing the second polysilicon layer 109b. With this method, however, it is not easy to control the height of the polysilicon layer formed in each of the tri-gate type transistor region R3 and the fin type transistor region R2. As a result, the process dispersion of the flattening processing becomes easy to necessarily exert the influence on this process.

As shown in FIG. 3I, an SiN film 110 is formed as a hard mask on the second polysilicon layer 109b in each of the tri-gate type transistor region R3 and the fin type transistor region R2, and the first polysilicon layer 109a and the second polysilicon layer 109b are then selectively etched away using the SiN film 110 as the mask by utilizing the RIE method, thereby forming gate electrodes 111 and 112. Thus, the basic shapes of the tri-gate type transistor and the fin type transistor are formed.

After that, after completion of processes for formation of a pn junction for formation of the source region and the drain region, formation of a pn junction for contact with a source electrode and a drain electrode, formation for a gate wiring, a source wiring and a drain wiring, and the like, the semiconductor device in which the tri-gate type transistor and the fin type transistor are formed is completed.

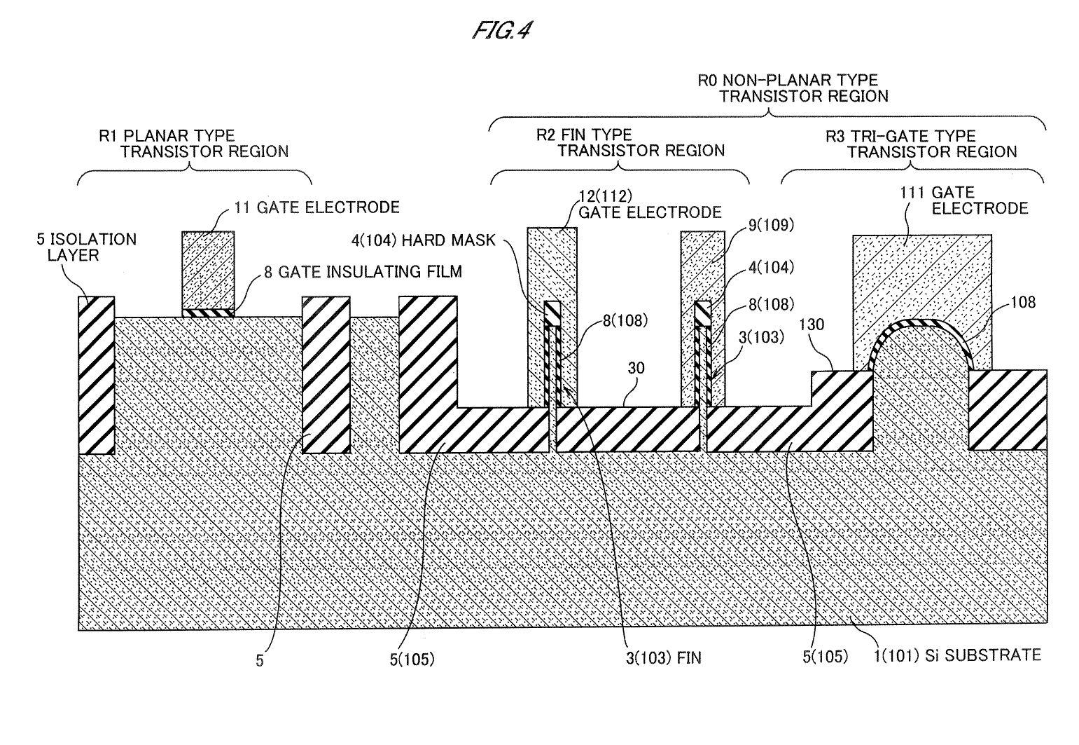

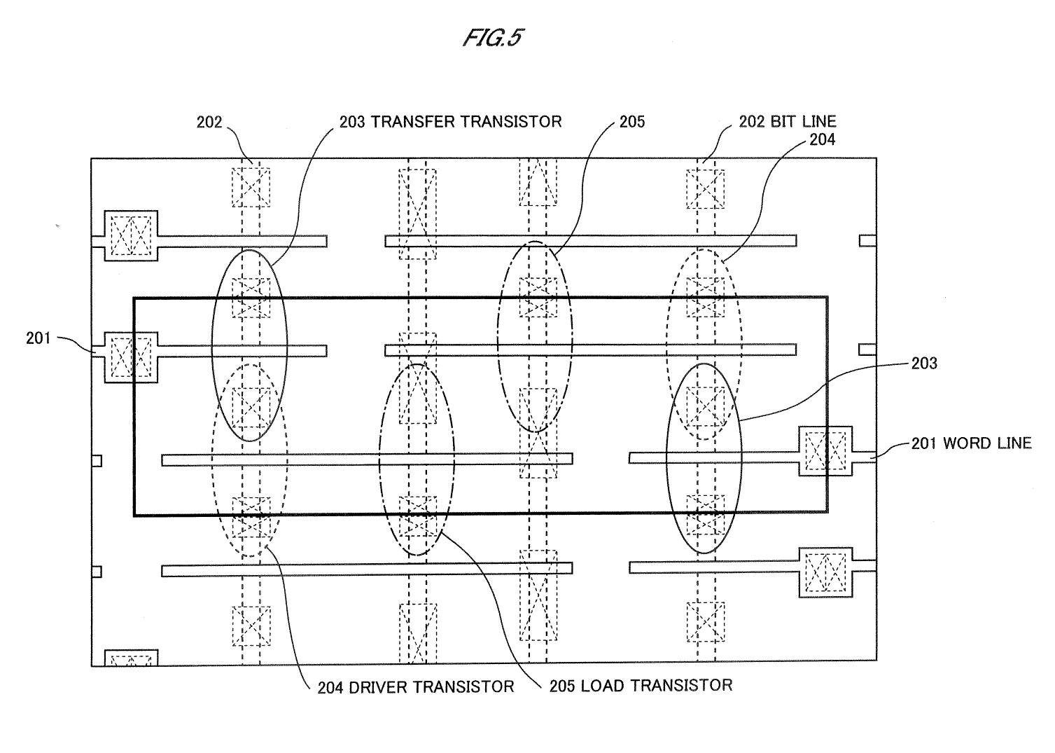

FIG. 4 shows a cross section of a semiconductor device, in which a planar type transistor, a tri-gate type transistor and a fin type transistor are formed on an Si substrate, according to a third embodiment of the present invention. That is to say, the cross section in a channel length direction is shown for the planar type transistor, and the cross sections in directions each perpendicularly intersecting the channel length direction are shown for the tri-gate type transistor and the fin type transistor, respectively. A semiconductor device in which a planar type transistor region R1, and a non-planar type transistor region R0 including a fin type transistor region R2 and a tri-gate type transistor region R3 are provided on an Si substrate 1, 101, and thus the three kinds of transistors are formed on the same substrate can be fabricated by combining the method of fabricating the semiconductor device having the planar type transistor and the fin type transistor formed therein described in the first embodiment and the method of fabricating the semiconductor device having the tri-gate type transistor and the fin type transistor formed therein described in the second embodiment with each other. In particular, in the etching processing for the isolation layers 5 and 105 as the buried insulating films in the planar type transistor region R1, the tri-gate type transistor region R3, and the fin type transistor region P2, the buried insulating films in the planar type transistor region R1, the tri-gate type transistor region R3, and the fin type transistor region R2 can be formed so as to have the etching surfaces 30 and 130 having different heights, respectively.

A semiconductor device according to a fourth embodiment of the present invention includes an SRAM element.

In a static random access memory (SRAM) involving an increase in occupation area and dispersion of threshold voltages as fatal shortcomings, a design of an SRAM cell using the fin type transistors is expected with the progress of the technology node.

On the other hand, the planar type transistors which are mainly currently used are desirably applied to the circuit for reading out/writing data from/to the SPAM cell, or the peripheral circuit such as the sense amplifier on the two grounds that (1) such a circuit has the looser design rules than those for an SRAM cell portion, and (2) it is not easy to fabricate such a circuit in the form of the fin type transistors, and also the effects in the fabrication thereof are poor because such a circuit does not have such a periodic and dense pattern as in the SRAM cell portion. Also, in addition to the peripheral circuit for the SRAM cell, a large number of circuit portions each of which does not necessarily have the high performance and the high integration exist on an SoC chip. From the above, the semiconductor device in which the planar type transistor in the fin type transistor are formed on one sheet of substrate is desired.

Then, the semiconductor devices according to the embodiments of the present invention are applied to an SRAM element. That is to say, the SRAM cell is structured in the form of the fin type transistors according to the above embodiments of the present invention, and the peripheral circuit of the SRAM cell is structured in the form of the planar type transistors according to the above embodiments of the present invention, which makes it possible to structure the SRAM element.

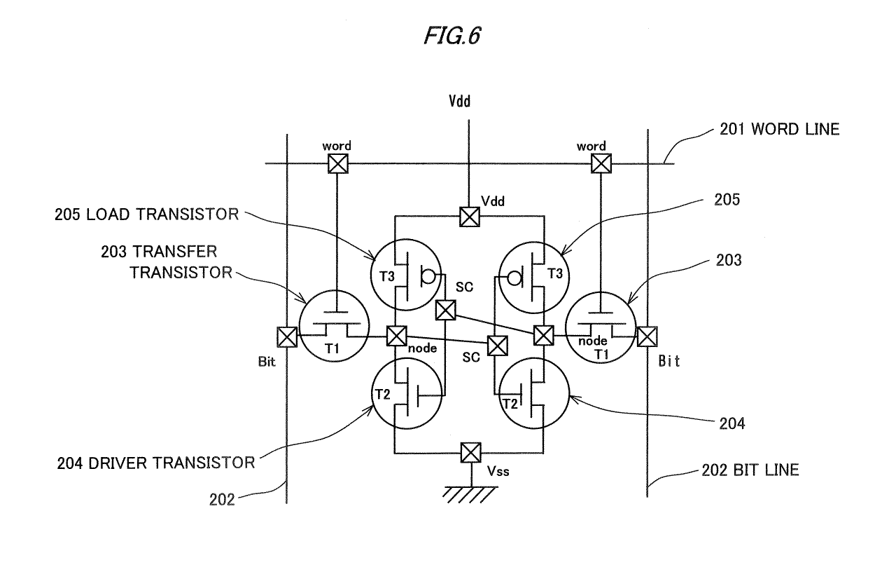

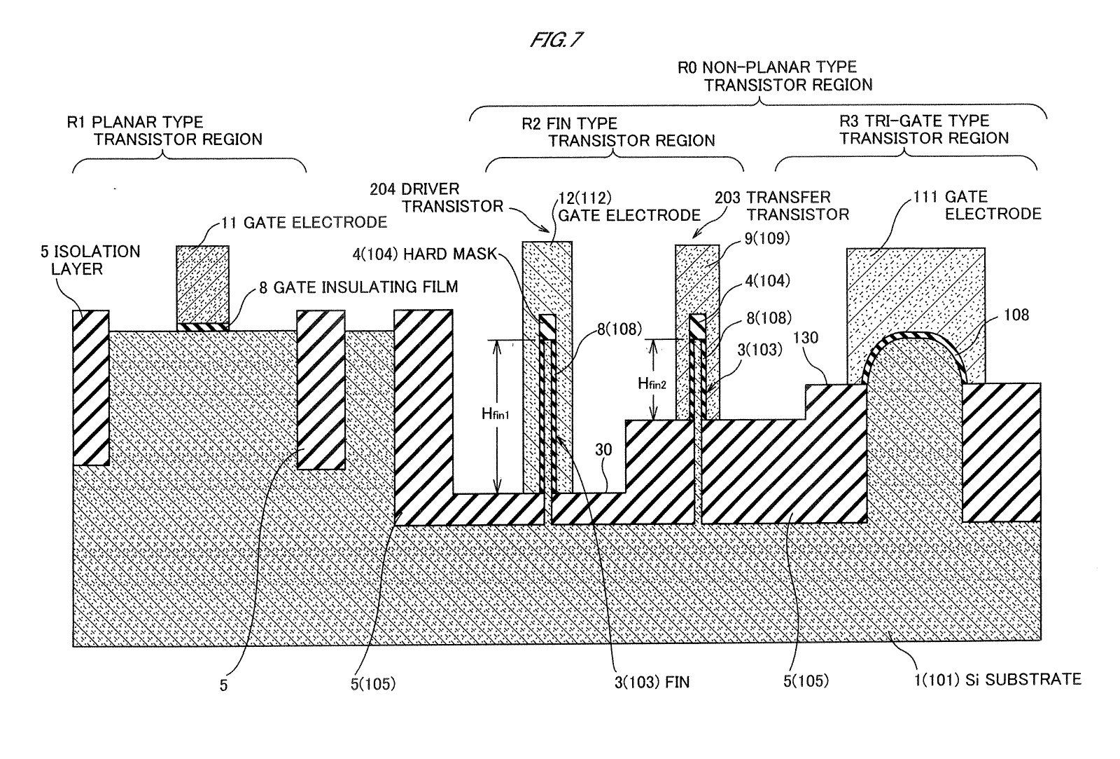

FIG. 5 shows a layout of an SRAM cell. The SRAM cell includes word lines 201, and bit lines 202 for element driving, two transfer transistors 203, two driver transistors 204, and two load transistors 205. A concrete circuit diagram of the SRAM cell is as shown in FIG. 6.

When the SRAM cell receives as its input data (1 or 0) to be written as data, and an suitable voltage is applied to a word line 201, each of the transfer transistors 203 conducts between corresponding source and drain, thereby writing the data in the SRAM cell. The data thus written is held in a flip-flop circuit. In a phase of reading out data, when each of bit lines 202 as data lines is released (a state is provided in which there is no potential), and the suitable voltage is applied to the word line 201 again, each of the transfer transistors 203 conducts between the corresponding source and drain, thereby outputting the data thus held in the flip-flop circuit.

FIG. 7 shows a cross section of a semiconductor device in which a planar type transistor, a tri-gate type transistor and a fin type transistor are formed on an Si substrate. The cross section in the channel length direction is shown for the planar type transistor, and the cross sections in directions each perpendicularly intersecting the channel length direction are shown for the tri-gate type transistor and the fin type transistor, respectively. The transfer transistor 203 and the driver transistor 204 of the SRAM cell described above are shown in a fin type transistor region R2. An etching surface 30, 130 of an isolation layer 5, 105 as a buried insulating film in the region having the driver transistor 204 formed therein is formed to have a lower height than that of an etching surface 30, 130 of the isolation layer 5, 105 in a region having the transfer transistor 203 formed therein. As a result, a fin 3, 103 of the driver transistor 204 is formed to have a larger height H_{fin2} than that H_{fin2} of the fin 3, 103 of the transfer transistor 203.

This structure is formed by utilizing the fabricating method shown in FIG. 1D or FIG. 3D. That is to say, an amount of etched back driver transistor 204 region is made more than that of etched back transfer transistor 203 region, which results in that the fin 3, 103 of the driver transistor 204 can be formed to have the larger height H_{fin1} than that H_{fin2} of the fin 3, 103 of the transfer transistor 203.

According to the first to fourth embodiments of the present invention, the following effects can be obtained.

1. Since the fin type transistor including the fin having the arbitrarily set height can be structured, the characteristics of the fin type transistor can be changed so as to meet a requirement of a circuit structure. In particular, the increasing of the height of the fin allows the operating current to be increased without increasing the occupation area even when the high integration is realized.

2. Since the fins of a plurality of fin type transistors can be formed to have different heights, the characteristics can be set in accordance with the function of the fin type transistor in the semiconductor device.

3. In the portion constituting the fin of the tri-gate type transistor, the rounding processing for rounding off the corner portions can be performed in accordance with presence or absence of the hard mask. Therefore, it is possible to prevent that the electric field is concentrated on each of the corner portions and thus each of the corner portions is turned on earlier than the flat portion is turned on. As a result, the stable circuit operation becomes possible.

4. In the example of application to the SRAM cell, the fin of the driver transistor can be formed to have the larger height than that of the fin of the transfer transistor. As a result, since the performance (driving current) of the driver transistor can be made more excellent than that of the transfer transistor, the static noise margin (SNM) can be improved without being accompanied with an increase in cell area and an increase in reference voltage.

5. The characteristics of the individual semiconductor elements of the semiconductor device in which the planar type transistor and the fin type transistor or the tri-gate type transistor are formed on the substrate can be changed while the stored library relating to the planar type transistors is effectively utilized. As a result, the semiconductor device having the desired characteristics and the method of fabricating the same become possible. Also, in particular, the effect can be especially obtained in the semiconductor device having the SRAM formed therein because the SNM as the important characteristics of the SRAM can be improved.

It should be noted that each of the first to fourth embodiments of the present invention is merely an embodiment, the present invention is not intended to be limited thereto, and the various changes thereof can be made without departing from the gist of the invention. In addition, the constituent elements of each of the first to fourth embodiments can be arbitrarily combined with one another without departing from the gist of the invention.

What is claimed is:

1. A semiconductor device, comprising:
a semiconductor substrate;
a non-planar type transistor region having at least one of a fin type transistor region including a fin type transistor in which a current is induced to flow through side faces of a fin formed approximately vertically to a surface of the semiconductor substrate in a direction approximately parallel to the surface of the semiconductor substrate, and a tri-gate type transistor region including a tri-gate type transistor in which a channel is formed in three surfaces having side faces and an upper surface of a fin formed approximately vertically to the surface of the semiconductor substrate, and thus a current is induced to flow through the three surfaces in a direction approximately parallel to the surface of the semiconductor substrate; and
a filling material for isolation in the non-planar type transistor region within the semiconductor substrate and which has a plurality of regions having different heights.

2. A semiconductor device according to claim 1, further comprising:
a planar type transistor region including a planar type transistor in which a current is induced to flow in a direction approximately parallel to the surface of the semiconductor substrate; and
a filling material for isolation in the planar type transistor region within the semiconductor substrate and which has a height higher than that of the filling material for isolation in the non-planar type transistor region.

3. A semiconductor device according to claim 2, wherein an SRAM cell is formed in the fin type transistor region, and a peripheral circuit of the SRAM cell is formed in the planar type transistor region.

4. A semiconductor device according to claim 3, wherein the SRAM cell includes a driver transistor and a transfer transistor, and a fin of the driver transistor is higher than that of the transfer transistor.

5. A semiconductor device according to claim 1, wherein the filling material for isolation in the non-planar type transistor region includes a filling material for isolation in the fin type transistor region, and a filling material for isolation in the tri-gate type transistor region, of which a height is different from that of the filling material for isolation in the fin type transistor region.

6. A semiconductor device according to claim 5, wherein the filling material for isolation in the tri-gate type transistor region has a height higher than that of the filling material for isolation in the fin type transistor region.

7. A semiconductor device according to claim 5, wherein the tri-gate type transistor has a fin upper corners of which are rounded off.

8. A semiconductor device according to claim 1, wherein two or more kinds of fin type transistors having different fin heights are formed in the fin type transistor region.

9. A semiconductor device according to claim 8, wherein the two or more kinds of fin type transistors having different fin heights have adjacent regions of a filling material for isolation in the fin type transistor region which are different in height from each other.

10. A semiconductor device according to claim 2, wherein the filling material for isolation in the non-planar type transistor region includes a filling material for isolation in the fin type transistor region, and a filling material for isolation in the tri-gate type transistor region, of which a height is different from that of the filling material for isolation in the fin type transistor region.

11. A semiconductor device according to claim 10, wherein the filling material for isolation in the tri-gate type transistor region has a height higher than that of the filling material for isolation in the fin type transistor region.

12. A semiconductor device, comprising:
a semiconductor substrate;
a planar type transistor region including a planar type transistor in which a current is induced to flow in a direction approximately parallel to a surface of the semiconductor substrate;
a fin type transistor region including a plurality of fin type transistors in which a current is induced to flow through side faces of a fin formed approximately vertically to the surface of the semiconductor substrate in a direction approximately parallel to the surface of the semiconductor substrate;
a filling material for isolation in the fin type transistor region within the semiconductor substrate and which has a plurality of regions having different heights; and
a filling material for isolation in the planar type transistor region within the semiconductor substrate and which has a height higher than that of the filling material for isolation in the fin type transistor region.

13. A semiconductor device according to claim 12, further comprising:
a tri-gate type transistor region including a tri-gate type transistor in which a channel is formed in three surfaces having side faces and an upper surface of a fin formed approximately vertically to the surface of the semiconductor substrate, and thus a current is induced to flow through the three surfaces in a direction approximately parallel to the surface of the semiconductor substrate; and
a filling material for isolation in the tri-gate type transistor region within the semiconductor substrate and which has a height lower than that of the filling material for isolation in the planar type transistor region.

14. A semiconductor device according to claim 13, wherein the filling material for isolation in the tri-gate type transistor region has a height higher than that of the filling material for isolation in the fin type transistor region.

15. A method of fabricating a semiconductor device, comprising:
forming a trench on a semiconductor substrate;
filling a dielectric material in the trench;
etching back the dielectric material film in a fin type transistor region in which a plurality of fin type transistors are intended to be formed while an etching depth is changed every predetermined region, thereby forming a filling material for isolation in the fin type transistor region having a plurality of regions having different heights; and
forming the fin type transistors in the fin type transistor region.

16. A method of fabricating a semiconductor device according to claim 15, wherein the filling material for isolation in the fin type transistor region is formed by performing selective etching using a photolithography technique.

17. A method of fabricating a semiconductor device according to claim 15, wherein filling the dielectric material comprises filling the dielectric material in the trench in a planar type transistor region in which a planar type transistor is intended to be formed, thereby forming a filling material for isolation in the planar type transistor region.

18. A method of fabricating a semiconductor device according to claim 17, wherein in forming the filling material for isolation in the fin type transistor region, the dielectric material in the fin type transistor region is etched back without etching the dielectric material in the planar type transistor region.

19. A method of fabricating a semiconductor device according to claim 15, wherein filling the dielectric material comprises filling the dielectric material in the trench in a tri-gate type transistor region in which a tri-gate type transistor is intended to be formed, and the dielectric material in the tri-gate type transistor region is etched back with an etching depth being changed from that of the fin type transistor region, thereby forming a filling material for isolation in the tri-gate type transistor region.

20. A method of fabricating a semiconductor device according to claim 19, further comprising:
selectively applying rounding processing to a fin of a tri-gate type transistor formed in the tri-gate type transistor region, thereby rounding off upper corner portions of the fin.
